(19) United States
(12) Patent Application Publication
(10) Pub. No.: US 2004/0001307 A1
(43) Pub. Date: Jan. 1, 2004

(54) Information processing apparatus having a detachable keyboard

(75) Inventor: Masahiko Takakusaki, Ome-shi (JP)

Correspondence Address: Pillsbury Winthrop LLP, Suite 2800, 725 South Figueroa Street, Los Angeles, CA, 90017-5406, US

(73) Assignee: Kabushiki Kaisha Toshiba, Tokyo (JP)

(21) Appl. No.: 10/458,694

(22) Filed: Jun. 10, 2003

(30) Foreign Application Priority Data
Jun. 28, 2002 (JP) 2002-191396

(51) Int. Cl. H05K 5/00

(52) U.S. Cl. 361/683

(57) ABSTRACT

An information processing apparatus includes a body and a keyboard detachably attached to the body. A first connector is provided in the body and is electrically connected to the keyboard. A first radio communication section is provided in the body. A second connector is provided in the keyboard and is connectable to the first connector to transfer a signal when the keyboard is attached to the body. A second radio communication section is provided in the keyboard to transmit/receive a radio signal to/from the first radio communication section when the keyboard is removed from the body.

### CROSS-REFERENCE TO RELATED APPLICATIONS

This application is based upon and claims the benefit of priority from prior Japanese Patent Application No. 2002-191396, filed Jun. 28, 2002.

### BACKGROUND OF THE INVENTION

1. Field of the Invention

The present invention relates to an information processing apparatus having a keyboard that is detachably connected to a body.

2. Description of the Related Art

In an information processing apparatus, such as a notebook personal computer, an input apparatus, in particular, a keyboard, is arranged on an upper surface of the case main body. The user inputs data through the keyboard in a state where he or she is situated near the display.

In the notebook personal computer, since the keyboard is fixed to the main body, the distance between the user and the display is limited within a certain range, and the degree of freedom of operating conditions is restricted.

Furthermore, the keyboard is connected to the computer main body through a cable. In this case, also, the operating environment of the user does not have a high degree of freedom.

### BRIEF SUMMARY OF THE INVENTION

Embodiments of the present invention provide an information processing apparatus, which improves the degree of freedom of an input operation, and in which the keyboard is freely attached to or removed from the main body, and even if the keyboard is removed from the main body, the user can perform an input operation easily and reliably.

According to one aspect of the present invention, there is provided an information processing apparatus having a body and a keyboard detachably attached to the body. A first connector is provided in the body and is electrically connected to the keyboard. A first radio communication section is provided in the body. A second connector is provided in the keyboard and is connectable to the first connector to transfer a signal when the keyboard is attached to the body. A second radio communication section is provided in the keyboard and transmits/receives a radio signal to/from the first radio communication section when the keyboard is removed from the body.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is an external perspective view showing a state in which a personal computer according to an embodiment of the present invention is opened;

FIG. 2 is an external perspective view showing a state in which the keyboard is being removed from the case body of the embodiment;

FIG. 3 is an external perspective view showing a state in which the keyboard has been removed from the case body of the embodiment;

FIG. 4 is a block diagram showing a circuit configuration of a main part of the information processing apparatus main body of the embodiment;

FIG. 5 is a block diagram showing a circuit configuration of the keyboard side of the embodiment; and

FIG. 6 is a flowchart showing an operation for checking the battery remaining amount in the keyboard side of the embodiment.

### DETAILED DESCRIPTION

Embodiments of the present invention will be described below with reference to the drawings.

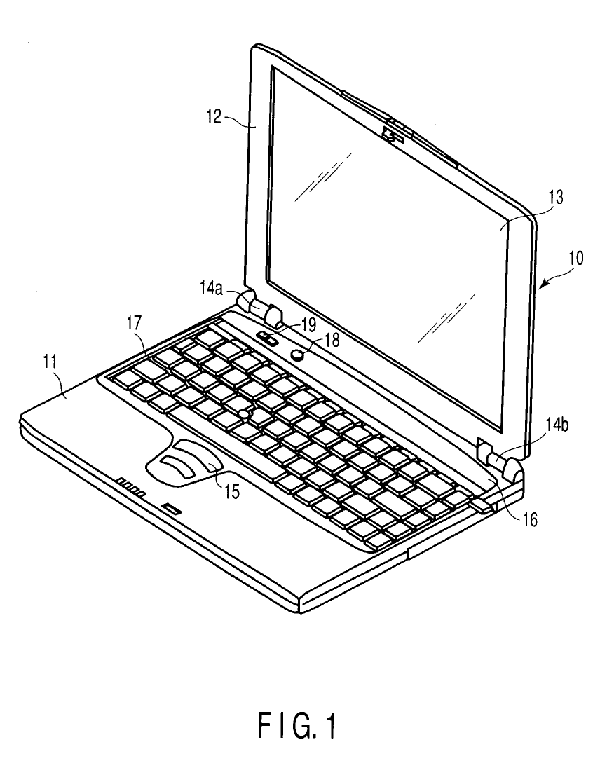

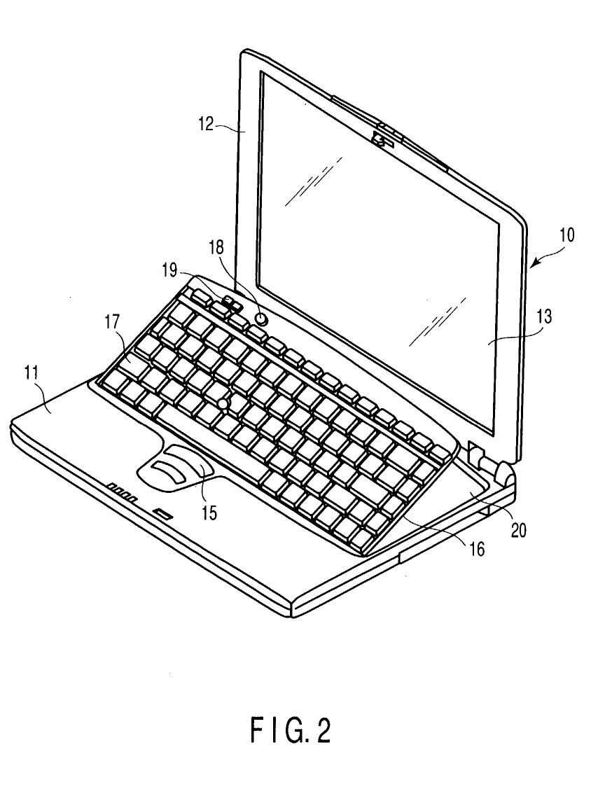

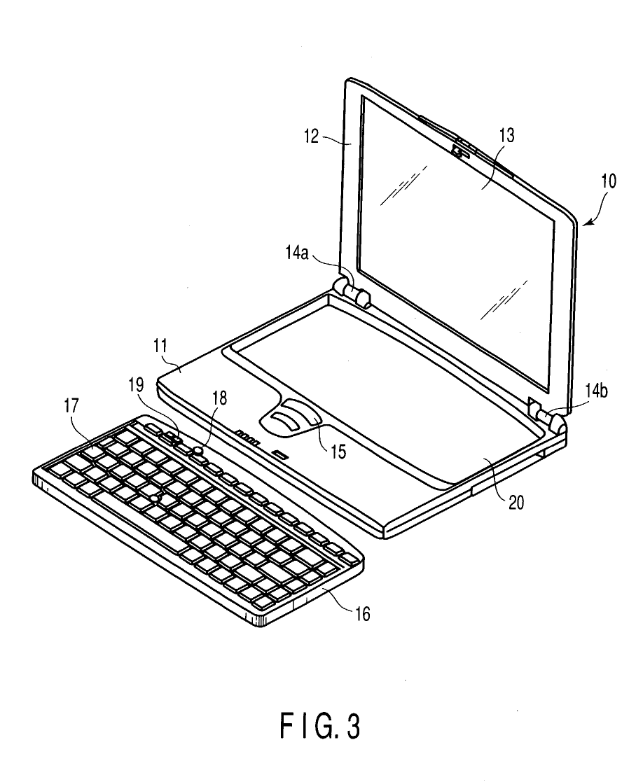

FIG. 1 is an external perspective view showing an example in which the present invention is applied to an information processing apparatus, for example, a notebook personal computer; FIG. 2 is an external perspective view showing a state in which the keyboard is being removed from the case body; and FIG. 3 is an external perspective view showing a state in which the keyboard has been removed from the case body.

Referring to FIG. 1, a personal computer 10 includes a case body 11 and a lid body 12. A display device, such as a liquid crystal display (LCD) panel 13, is provided on the inner surface of the lid body 12, i.e., the surface which faces the case body 11. The lid body 12 is rotatably supported by hinges 14a and 14b connected to a rear end portion of the case body 11.

A pointing device 15 and a keyboard 16 are provided on the upper surface of the case body 11. As shown in FIG. 2, the keyboard 16 is detachably attached to a recess 20 formed in an upper surface side of the case body 11 by an attachment member (not shown) or screws, or the like. It has a key group 17, a power switch (power SW) 18, a radio on/off switch (radio on/off SW) 19, etc., on its upper surface. It also has a radio communication section, a channel switch, a connector, a battery, etc. (to be described in detail later), on its lower surface.

A main body side connector (to be described later), to be connected to a keyboard side connector, is provided in the recess 20. When the keyboard 16 is fitted in the recess 20 of the case body 11, the keyboard side connector is coupled to the main body side connector. As a result, the system of the keyboard side is connected to the processing apparatus main body (main body system) through the connector. The connector transfers signals between the processing apparatus main body and the keyboard 16, and supplies electric power from the processing apparatus main body to the keyboard 16.

The keyboard 16 is configured to perform communications with the processing apparatus main body via the radio communication section, when it is separated from the case body 11, so that a key operation signal (key code) is transmitted to the processing apparatus main body. Further, a connection detecting section is provided on the lower surface of the keyboard 16 to detect a state of connection between the main body side connector and the keyboard side connector, as will be described later in detail.

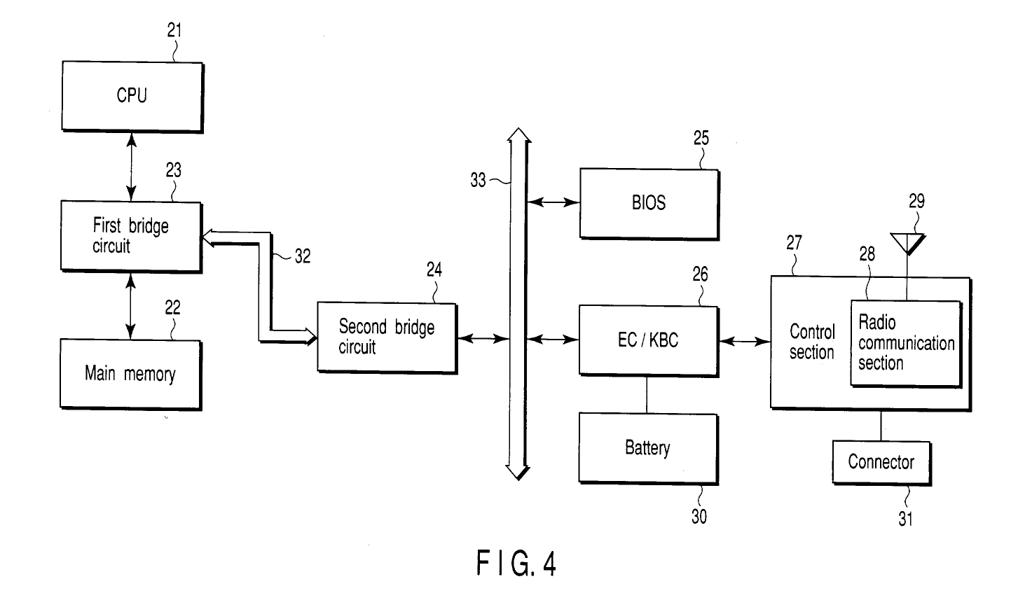

A main circuit configuration of the processing apparatus main body on the case body 11 side of the personal computer 10 will now be described with reference to FIG. 4.

As shown in FIG. 4, the main part of the processing apparatus main body includes a CPU 21, a main memory 22, a first bridge circuit 23, a second bridge circuit 24, a BIOS-ROM 25, an embedded controller/keyboard controller (EC/KBC) 26, a control section 27, a radio communication section 28, a radio communication antenna 29, a battery 30, and a main body side connector 31. The radio communication antenna 29 is arranged on, for example, a front-end side of the case body 11.

The CPU 21 controls the overall system. The CPU 21 operates in accordance with a control program (BIOS) stored in the BIOS-ROM 25. The main memory 22 is a memory device, in or from which the CPU 21 can write or read data. It temporarily stores necessary data as the CPU 21 performs a control operation.

The first bridge circuit 23 is a bridge device bi-directionally connecting a local bus of the CPU 21 and a hub link 32. The second bridge circuit 24 is a bridge device bi-directionally connecting the hub link 32 and a low-pin count (LPC) bus 33.

The LPC bus 33 is connected to the BIOS-ROM 25 and the EC/KBC 26. The EC/KBC 26 is supplied with power from the battery 30 and connected to the control section 27. The control section 27 is connected to the main body side connector 31. The battery 30 is charged by a power source unit using an AC adapter (not shown).

The EC/KBC 26 and the control section 27 are connected by a PS/2 interface.

The control section 27 includes the radio communication section 28. It converts a signal received through the radio communication section 28 into PS/2 format data, and controls transmission of a signal transmitted from the radio communication section 28 and the main body side connector 31.

The EC/KBC 26 is a controller to control additional functions of the system. It has power source sequence control functions (e.g., a system power source on/off function, a standby function, and a hibernation function), a keyboard control function, and a radio communication control function for the radio communication section 28.

The standby function turns off the display screen and suspends the CPU 21 and other devices, while the power is on. When the power switch 18 is depressed in the standby state, the previous condition is quickly reproduced. The hibernation function causes the contents of the memory to be stored in the hard disk (not shown), when the power of the processing apparatus main body is turned off. When the power switch 18 is depressed in the hibernation state, the previous condition is quickly reproduced. A shutdown function for turning off the power, the standby function and the hibernation function can be designated using an operation menu or specific function keys.

The EC/KBC 26 does not supply power to the radio communication section 28 in the state where the keyboard 16 is attached to the case body 11. When the keyboard 16 is removed from the case body 11, the EC/KBC 26 supplies power to the radio communication section 28.

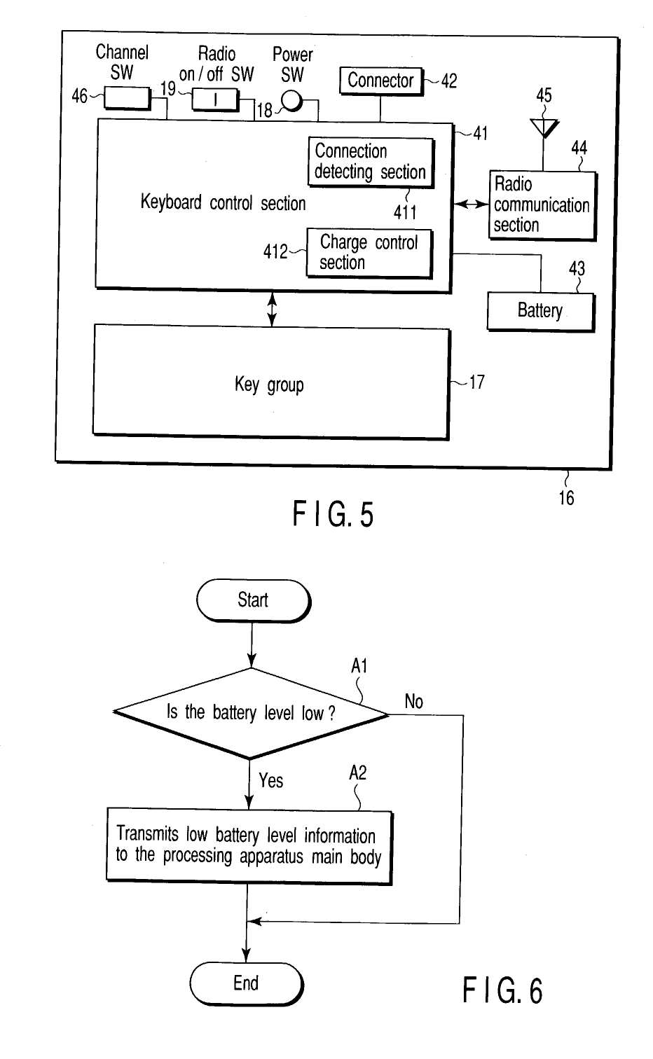

The main body side connector 31 is provided in the recess 20 of the case body 11 as descried above, and electrically connected to the keyboard side connector 42 shown in FIG. 5, when the keyboard 16 is fitted in the recess 20. At this time, if the EC/KBC 26 is supplied with power from the AC adapter, it supplies the power to the keyboard 16 through the main body side connector 31 and the keyboard side connector 42.

Further, the EC/KBC 26 supplies charging power to the battery 43, when the AC adapter is connected or a predetermined amount or more of electricity remains in the battery 30. For example, it may operate so as to supply the charging power to the battery 43 in the keyboard 16 if a predetermined amount or more of electricity remains in the battery 30, and not to supply the charging power if less electricity remains in the battery 30.

The radio communication section 28 is power-supplied and operated by control of the EC/KBC 26, when the keyboard 16 is removed from the recess 20 of the case body 11. It performs radio communications with the radio communication section 44 provided in the keyboard 16 as shown in FIG. 5 via the radio communication antenna 29. The radio communication section 28 basically receives signals transmitted from the radio communication section 44 of the keyboard 16. The radio communication sections 28 and 44 selectively use two channels in a 28 MHz band to carry out radio communications.

The system configuration of the keyboard 16 will now be described with reference to FIG. 5. The keyboard 16 includes the key group 17, a keyboard control section 41, the connector 42, the battery 43, the radio communication section 44, the radio communication antenna 45, the power switch 18, the radio on/off switch 19, and the channel switch 46. The keyboard control section 41 controls the overall keyboard 16. It includes a connection detecting section 411 to detect a state of connection between the connectors 31 and 42, and a charge control section 412 to control charge of the battery 43.

The keyboard side connector 42 is located under the keyboard 16. It is coupled to the main body side connector 31, when the keyboard 16 is attached to the recess 20 of the case body 11. The keyboard control section 41 detects a state of connection between the keyboard side connector 42 and the main body side connector 31 by the connection detecting section 411, and controls power supply to the radio communication section 44 and the battery 43 in accordance with the detected signal. More specifically, in the state where the keyboard side connector 42 is connected to the main body side connector 31, the keyboard control section 41 stops power supply to the radio communication section 44, and charges the battery 43 through the charge control section 412 with power supplied from the processing apparatus main body. When the charge of the battery 43 is completed, the charge control section 412 stops power supply to the battery 43.

In the state where the keyboard 16 is attached to the case body 11, the keyboard control section 41 transmits a key group 17 operating signal and a power switch 18 on/off signal to the processing apparatus main body through the keyboard side connector 42 and the main body side connector 31.

In the state where the keyboard 16 is removed from the case body 11, the keyboard control section 41 supplies power from the battery 43 to the radio communication section 44 to operate it, and transmits the key group 17 operating signal and the power switch 18 on/off signal to the radio communication section 28 of the processing apparatus main body through the radio communication antenna 45. The radio communication antenna 45 is arranged on, for example, a front-end side of the keyboard 16.

When the power of the battery 43 is supplied to the radio communication section 44 as described above, the keyboard control section 41 checks a voltage level of the battery 43 through the charge control section 412. When the level is lowered to a low-battery state, the keyboard control section 41 transmits information representing the state to the processing apparatus main body by radio.

The radio on/off switch 19 stops the operations of the radio communication section 44 in a case where use of radio is prohibited, for example, in a hospital, an airplane, etc.

The channel switch 46 arranged on the lower side of the keyboard 16 switches between the communication channels of the radio communication section 44, in a case where the communication between the keyboard side radio communication section 44 and the processing apparatus main body side radio communication section 28 is interfered by another personal computer located nearby.

The overall operation of the above embodiment will now be described.

When the key group 17 is to be operated near the LCD panel 13 provided on the processing apparatus main body, the keyboard 16 is used as it is fitted in the recess 20 of the case body 11.

As the keyboard 16 is fitted in the recess 20 of the case body 11, the keyboard side connector 42 is coupled and electrically connected to the main body side connector 31. The keyboard control section 41 detects that the keyboard side connector 42 is connected to the main body side connector 31 by the connection detecting section 411, and stops the power supply to the radio communication section 44. At the same time, it transmits key group 17 and power switch 18 operating signals to the processing apparatus main body through the keyboard side connector 42 and the main body side connector 31. The keyboard control section 41 charges the battery 43 through the charge control section 412 with power supplied from the processing apparatus main body. The charge control section 412 checks the charge state of the battery 43, and stops supplying power to the battery 43 when the charge is completed.

In the processing apparatus main body, when the keyboard 16 is attached to the case body 11 and the main body side connector 31 and the keyboard side connector 42 are connected to each other, the EC/KBC 26 detects the state and stops power supply to the radio communication section 28. The EC/KBC 26 carries out power source on/off control in accordance with the power switch 18 and key group 17 operating signals supplied through the main body side connector 31 and the keyboard side connector 42. When the power is on, the EC/KBC 26 outputs a signal corresponding to the operation of each key of the key group 17 to the CPU 21 through the LPC bus 33, the second bridge circuit 24, the hub link 32 and the first bridge circuit 23. The CPU 21 executes the process corresponding to an operation of the key group 17.

When the standby or hibernation function is designated, the EC/KBC 26 executes a control operation of the designated function, in addition to the power on/off control. When the power switch 18 is depressed in the standby or hibernation state, the EC/KBC 26 restores the state to the previous state.

As described above, in the state where the keyboard 16 is attached to the case body 11, signal transmission between the keyboard 16 and the processing apparatus main body is executed through the keyboard side connector 42 and the main body side connector 31.

When the key group 17 is to be operated at a position a little further apart from the LCD panel 13 provided on the processing apparatus main body, the keyboard 16 is used as it is removed from the recess 20 of the case body 11.

When the keyboard 16 is removed from the case body 11, the keyboard side connector 42 is separated from the main body side connector 31. The keyboard control section 41 always checks the state of connection between the keyboard side connector 42 and the main body side connector 31 by the connection detecting section 411. When it detects that the connection therebetween is cut, it checks the on/off state of the radio on/off switch 19. If the switch 19 is in the on state, the keyboard control section 41 supplies power from the battery 43 to the radio communication section 44. If the radio on/off switch 19 is in the off state, the power supply to the radio communication section 44 is not carried out.

The keyboard control section 41 checks the channel designated by the channel switch 46, sets a communication channel of the radio communication section 44, and inputs the power switch 18 operating signal and the key group 17 operating signal to the radio communication section 44.

The radio communication section 44 is operated when it is supplied with power from the battery 43. It transmits the power switch 18 operating signal and the key group 17 operating signal to the processing apparatus main body through the radio communication antenna 45.

When no key operation is executed in a preset time period or longer, the keyboard control section 41 cuts off power supply to the radio communication section 44 to save power consumption. When a key operation is performed thereafter, the keyboard control section 41 starts supplying power to the radio communication section 44.

In a case where the communication between the keyboard 16 and the processing apparatus main body is interfered by another personal computer located nearby, the channel switch 46 switches the communication channel of the radio communication section 44 to another channel.

In the processing apparatus main body, when the keyboard 16 is removed from the case body 11 and the main body side connector 31 and the keyboard side connector 42 are disconnected from each other, the EC/KBC 26 detects the state and supplies power to the radio communication section 28. As a result, the radio communication section 28 is set to a standby state for receiving a signal. In the standby state for receiving a signal, power is supplied to the radio communication section 28 at predetermined time intervals. More specifically, power is supplied at intervals of time, in which the radio communication section 28 can detect a signal supplied from the radio communication section 44 of the keyboard 16. As a result, power consumption can be saved.

Once the EC/KBC 26 receives through the radio communication section 28 the operation signal sent from the radio communication section 44 of the keyboard 16, it thereafter continuously supplies power to the radio communication section 28. However, when it does not receive a signal from the keyboard 16 in a preset time period or longer, it sets the radio communication section 28 again in the standby state for receiving a signal.

The EC/KBC 26 receives through the radio communication section 28 an operation signal transmitted from the radio communication section 44 of the keyboard 16, and executes the process corresponding to the received signal. More specifically, the EC/KBC 26 executes power on/off control in accordance with the power switch 18 or key group 17 operating signal transmitted from the keyboard 16 by radio. When the power is on, the EC/KBC 26 executes a control operation with respect to the input operation of each key of the key group 17. When the standby or hibernation function is designated, the EC/KBC 26 executes a control operation of the designated function, in addition to the power on/off control. When the power switch 18 is depressed in the standby or hibernation state, the EC/KBC 26 restores the state to the previous state.

After the keyboard 16 is removed from the case body 11, when a first communication is performed between the keyboard side radio communication section 44 and the main body side radio communication section 28, the CPU 21 displays the number of the channels used for the communication in a part of the screen. The channel number is continuously displayed for a predetermined time or until a next key operation is carried out. In addition, when the channel switch 46 switches the channel, the new channel number is displayed on the screen.

As described above, even when the keyboard 16 is removed form the case body 11, the same operation as in the case where the keyboard 16 is attached to the case body 11 can be performed. Thus, the degree of freedom in the operating environment of the user can be remarkably improved.

Further, as shown in the flowchart of FIG. 6, when the processing apparatus is used with the keyboard 16 removed from the case body 11, the keyboard control section 41 checks by the charge control section 412 whether the level of the battery is low at predetermined time intervals (step A1). When the low battery level is detected, the keyboard control section 41 transmits low battery level information to the processing apparatus main body through the radio communication section 44 (step A2).

When the CPU 21 of the processing apparatus main body receives the information representing that the battery level has been low from the keyboard 16, it displays on the LCD panel 13 a popup message such as “The battery level is low. Connect the keyboard to the main body for charge.” The user is informed by the popup message that the battery level is low, and should connect the keyboard 16 to the case body 11 to charge the battery 43.

As described above, according to the present invention, the keyboard can be freely attached to or removed from the processing apparatus main body. Moreover, even if the keyboard is removed from the processing apparatus main body, the user can perform an input operation easily and reliably. As a result, the degree of freedom of the input operation can be remarkably improved.

What is claimed is:

1. An information processing apparatus, comprising:
a body;
a keyboard detachably attached to the body;
a first connector provided in the body and electrically connected to the keyboard;
a first radio communication section provided in the body;
a second connector provided in the keyboard and connectable to the first connector to transfer a signal when the keyboard is attached to the body; and
a second radio communication section provided in the keyboard to transmit/receive a radio signal to/from the first radio communication section when the keyboard is detached from the body.

2. The information processing apparatus according to claim 1, wherein the keyboard includes a power switch to turn on and off power to the body.

3. The information processing apparatus according to claim 2, wherein the body has standby and hibernation functions, and executes a process of recovering from standby and hibernation in response to a power switch operating signal supplied from the keyboard.

4. The information processing apparatus according to claim 1, wherein the keyboard includes a battery and a charge control section to charge the battery with power supplied from the body when the keyboard is attached to the body.

5. The information processing apparatus according to claim 4, wherein the keyboard includes a connection detecting section to detect whether the keyboard is connected to the body via the first connector and the second connector, and when the connection detecting section detects that the keyboard is not connected to the body, the keyboard provides power from the battery to the second radio communication section.

6. The information processing apparatus according to claim 4, wherein the keyboard includes a connection detecting section to detect whether the keyboard is connected to the body via the first connector and the second connector, and when the connection detecting section detects that the keyboard is connected to the body, the keyboard cuts off power from the battery to the second radio communication section.

7. The information processing apparatus according to claim 4, wherein the keyboard is capable of detecting a battery level, and when the keyboard detects that the battery level is low, the keyboard transmits information to the body indicating that the battery level is low.

8. The information processing apparatus according to claim 7, wherein when the body receives the information representing that the battery level is low, the body displays on a screen information notifying that the battery requires charging.

9. An information processing apparatus, comprising:
a body;
a keyboard detachably attached to the body;
a first connector provided in the body and electrically connected to the keyboard;
a first radio communication section provided in the body;
a second connector provided in the keyboard and connectable to the first connector to transfer a signal when the keyboard is attached to the body;
a second radio communication section provided in the keyboard to transmit/receive a radio signal to/from the first radio communication section when the keyboard is detached from the body;
a first power supply control section provided in the body to supply power to a battery of the keyboard and to cut off power to the first radio communication section when the first connector and the second connector are connected; and
a second power supply control section provided in the keyboard to cut off power to the second radio communication section when the first connector and the second connector are connected.

10. The information processing apparatus according to claim 9, wherein the keyboard includes a power switch to turn on and off power to the body, the body has standby and hibernation functions, and when the standby function or the hibernation function is designated, a process of recovering from the standby function or the hibernation function is executed in response to a power switch operating signal supplied from the keyboard.

11. The information processing apparatus according to claim 10, wherein the first power supply control section provided in the body charges the battery of the keyboard only when an AC adapter is connected to the body and at least a predetermined amount of electricity remains in the battery when the keyboard is attached to the body.

12. An information processing apparatus, comprising:
a body;
keyboard means, detachably attached to the body, for receiving input;
first connector means, provided in the body and electrically connected to the keyboard means, for transmitting/receiving signals;
first radio communication means, provided in the body, for transmitting/receiving radio signals;
second connector means, provided in the keyboard means and connectable to the first connector means, for transferring a signal when the keyboard means is attached to the body; and
second radio communication means, provided in the keyboard means, for transmitting/receiving a radio signal to/from the first radio communication means when the keyboard means is detached from the body.

13. The information processing apparatus according to claim 12, wherein the keyboard means includes power switch means for turning on and off power to the body.

14. The information processing apparatus according to claim 13, wherein the body has standby and hibernation functions, and executes a process of recovering from standby and hibernation in response to a power switch operating signal supplied from the keyboard means.

15. The information processing apparatus according to claim 12, wherein the keyboard means includes a battery and charge control means for charging the battery with power supplied from the body when the keyboard means is attached to the body.

16. The information processing apparatus according to claim 15, wherein the keyboard means includes connection detecting means for detecting whether the keyboard means is connected to the body via the first connector means and the second connector means, and when the connection detecting means detects that the keyboard means is not connected to the body, the keyboard means provides power from the battery to the second radio communication means.

17. The information processing apparatus according to claim 15, wherein the keyboard means includes connection detecting means for detecting whether the keyboard means is connected to the body via the first connector means and the second connector means, and when the connection detecting means detects that the keyboard means is connected to the body, the keyboard means cuts off power from the battery to the second radio communication means.

18. The information processing apparatus according to claim 15, wherein the keyboard means is capable of detecting a battery level, and when the keyboard means detects that the battery level is low, the keyboard means transmits information to the body indicating that the battery level is low.

19. The information processing apparatus according to claim 18, wherein when the body receives the information representing that the battery level is low, the body displays on a screen information notifying that the battery requires charging.

20. An information processing apparatus, comprising:
a body;
keyboard means, detachably attached to the body, for receiving input;
first connector means, provided in the body and electrically connected to the keyboard means, for transmitting/receiving signals;
first radio communication means, provided in the body, for transmitting/receiving radio signals;
second connector means, provided in the keyboard means and connectable to the first connector means, for transferring a signal when the keyboard means is attached to the body;
second radio communication means, provided in the keyboard means, for transmitting/receiving a radio signal to/from the first radio communication means when the keyboard means is removed from the body;
first power supply control means, provided in the body, for supplying power to a battery of the keyboard means and cutting off power to the first radio communication means when the first connector means and the second connector means are connected; and
second power supply control means, provided in the keyboard, for cutting off power to the second radio communication means when the first connector means and the second connector means are connected.

21. The information processing apparatus according to claim 20, wherein the keyboard means includes power switch means for turning on and off power to the body, the body has standby and hibernation functions, and when the standby function or the hibernation function is designated, a process of recovering from the standby function or the hibernation function is executed in response to a power switch operating signal supplied from the keyboard means.

22. The information processing apparatus according to claim 21, wherein the first power supply control means provided in the body charges the battery of the keyboard means only when an AC adapter is connected to the body and at least a predetermined amount of electricity remains in the battery when the keyboard means is attached to the body.
